(19) United States
(12) Patent Application Publication
(10) Pub. No.: US 2012/0044011 A1
(43) Pub. Date: Feb. 23, 2012

(54) INITIATING FORCED SHUTDOWN OF A DEVICE

(75) Inventor: Seppo Ilmari HELLE, Paimio (FI)

(73) Assignee: Nokia Corporation

(21) Appl. No.: 12/858,905

(22) Filed: Aug. 18, 2010

(51) Int. Cl. H03K 17/28

(52) U.S. Cl. 327/392

(57) ABSTRACT

A method comprises initiating generation of a feedback signal in response to determining that an input has been selected throughout a first predetermined period of time and initiating a forced shutdown of a device in response to determining that the input has been deselected within a second predetermined period of time after the initiating of the generation of the feedback signal.

### FIELD

The invention relates to initiating forced shutdown of a device.

### BACKGROUND

Devices such as mobile communication devices can be provided with a mechanism for turning off the power in certain circumstances, such as when the device is not responding.

### SUMMARY

According to a first aspect of the present invention, there is provided a method comprising initiating generation of a feedback signal in response to determining that an input has been selected throughout a first predetermined period of time, and initiating a forced shutdown of a device in response to determining that the input has been deselected within a second predetermined period of time after the initiating of the generation of the feedback signal.

The method may further comprise disabling the initiation of the forced shutdown of the device in response to determining that the input has remained selected throughout the second predetermined period of time after the initiating of the generation of the feedback signal.

The method may comprise entering a second state from an initial, first state in response to determining that the input has been selected, causing a first timer to start in response to entering the second state, the first timer defining the first predetermined period of time, entering a third state from the second state in response to determining that the input has not been deselected prior to expiry of the first timer, causing a second timer to start in response to entering the third state, the second timer defining the second predetermined time period, and initiating the forced shutdown in response to determining that the input has been deselected prior to expiry of the second timer.

The method may comprise entering the first, initial state from the second state in response to determining that the input has been deselected prior to expiry of the first timer.

The method may further comprise refraining from initiating forced shutdown in response to determining when in the third state that the input has not been deselected prior to expiry of the second timer.

The method may further comprise entering the first, initial state from the fourth state in response to determining that the input has been deselected.

The input may be an input to a single physical key.

Initiating forced shutdown may comprise causing removal of the supply of electrical power from an integrated battery.

The first predetermined period may be at least four times as long as the second predetermined period.

According to a second aspect of the present invention, there is provided apparatus comprising a determining device, and first and second initiating devices, wherein the determining device is configured to determine that an input has been selected throughout a first predetermined period of time, the first initiating device is configured to initiate generation of a feedback signal in response to the determining that the input has been selected throughout the first predetermined period of time, the determining device is further configured to determining that the input has been deselected within a second predetermined period of time after the initiating of the generation of the feedback signal, and the second initiating device is configured to initiate a forced shutdown of a device in response to the determining that the input has been deselected within the second predetermined period of time after the initiating of the generation of the feedback signal.

The determining device may be further configured to disable the initiation of the forced shutdown of the device in response to determining that the input has remained selected throughout the second predetermined period of time after the initiating of the generation of the feedback signal.

The determining device may be configured to cause the apparatus to enter a second state from an initial, first state in response to determining that the input has been selected, cause a first timer to start in response to entering the second state, the first timer defining the first predetermined period of time, cause the apparatus to enter a third state from the second state in response to determining that the input has not been deselected prior to expiry of the first timer, cause a second timer to start in response to entering the third state, the second timer defining the second predetermined time period, and determine that the input has been deselected prior to expiry of the second timer, and the second initiating devices may be configured to initiate the forced shutdown in response to the determining that the input has been deselected prior to expiry of the second timer.

The determining device may be configured to cause the apparatus to enter the first, initial state from the second state in response to determining that the input has been deselected prior to expiry of the first timer.

The determining device may be further configured to cause the apparatus to refrain from initiating forced shutdown in response to determining when in the third state that the input has not been deselected prior to expiry of the second timer.

The determining device may be further configured to cause the apparatus to enter the first, initial state from the fourth state in response to determining that the input has been deselected.

The input may be an input to a single physical key.

The second initiating device may be configured to initiate forced shutdown comprising causing removal of the supply of electrical power from an integrated battery.

The first and second initiating devices may constitute a single initiating device.

Determining circuitry may constitute the determining device, first initiating circuitry may constitute the first initiating device, and second initiating circuitry may constitute the second initiating device.

The apparatus may be the device and further comprise user interface circuitry and user interface software configured to facilitate user control of at least some functions of the device though use of a display and configured to respond to user inputs and a display and display circuitry configured to display at least a portion of a user interface of the device, the display and display circuitry configured to facilitate user control of at least some functions of the device.

According to a third aspect of the present invention, there is provided apparatus comprising determining circuitry, and first and second initiating circuitries, wherein the determining circuitry is configured to determine that an input has been selected throughout a first predetermined period of time, the first initiating circuitry is configured to initiate generation of a feedback signal in response to the determining that the input has been selected throughout the first predetermined period of time, the determining circuitry is further configured to determining that the input has been deselected within a second predetermined period of time after the initiating of the generation of the feedback signal, and the second initiating circuitry is configured to initiate a forced shutdown of a device in response to the determining that the input has been deselected within the second predetermined period of time after the initiating of the generation of the feedback signal.

According to a fourth aspect of the present invention, there is provided apparatus comprising at least one processor, and at least one memory including computer program code, the at least one memory and the computer program code configured to, with the at least one processor, cause the apparatus at least to perform initiating generation of a feedback signal in response to determining that an input has been selected throughout a first predetermined period of time, and initiating a forced shutdown of a device in response to determining that the input has been deselected within a second predetermined period of time after the initiating of the generation of the feedback signal.

According to a fifth aspect of the present invention, there is provided apparatus configured to initiate generation of a feedback signal in response to determining that an input has been selected throughout a first predetermined period of time and initiate a forced shutdown of a device in response to determining that the input has been deselected within a second predetermined period of time after the initiating of the generation of the feedback signal.

According to a sixth aspect of the present invention, there is provided apparatus comprising means for determining that an input has been selected throughout a first predetermined period of time, means for initiating generation of a feedback signal in response to the determining that the input has been selected throughout the first predetermined period of time, means for determining that the input has been deselected within a second predetermined period of time after the initiating of the generation of the feedback signal, and means for initiating a forced shutdown of a device in response to the determining that the input has been deselected within the second predetermined period of time after the initiating of the generation of the feedback signal.

### BRIEF DESCRIPTION OF THE DRAWINGS

Embodiments of the invention will now be described, by way of example only, with reference to the accompanying drawings, in which:

FIG. 1 shows a device in which example embodiments of the invention are implemented;

FIG. 2 illustrates some aspects of the hardware and software configuration of the device shown in FIG. 1;

FIG. 3 is a block diagram of apparatus included in the device shown in FIG. 1; and

FIG. 4 is a flow diagram illustrating operation of the apparatus shown in FIG. 3.

### DETAILED DESCRIPTION

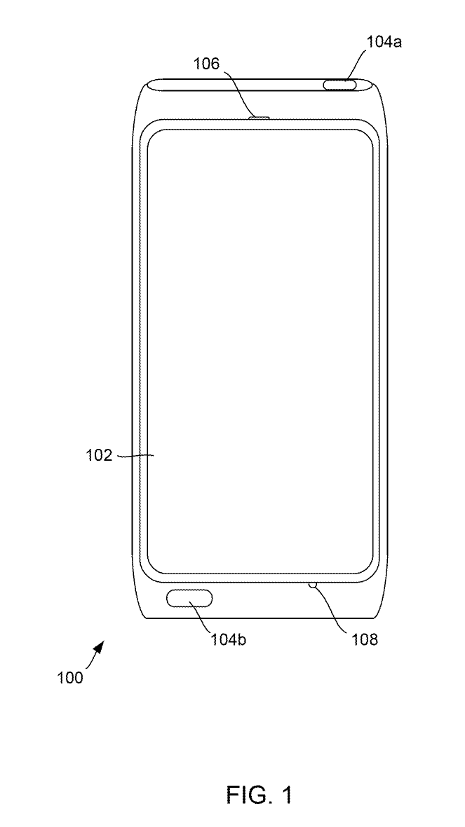

Referring to FIG. 1, a device 100 is shown. The device 100 embodies aspects of the invention and is not limiting on the scope of the invention. The device 100 has a touch sensitive display, or touchscreen 102 for displaying content and for receiving tactile user inputs. The device 100 also has at least two physical keys for receiving inputs from a user, including a power key 104a and a home key 104b. The device 100 also has at least one speaker 106 and at least one microphone 108. The device 100 may be a mobile computer, mobile phone, PDA, internet tablet, smartphone or other device.

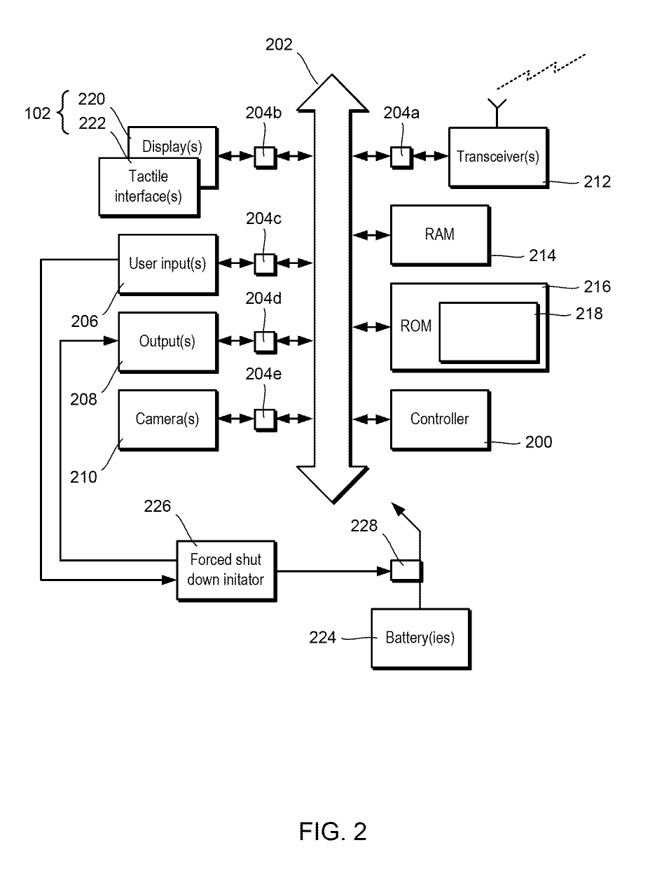

Referring mainly to FIG. 2, aspects of the hardware and software configuration of the device 100 are shown in more detail. The device 100 includes a controller 200 comprising one or more processors (not shown). The controller 200 communicates with the other hardware components via a system bus 202. Each other hardware component is connected to the system bus 202 either directly or via an interface (generally denoted by the numeral 204). The other hardware components include the touchscreen 102, user input means 206, output means 208 and at least one camera 210. The device 100 also contains at least one transceiver 212 connected to the system bus 202 via an interface 204a for communicating over a wireless link, such as a GSM, CDMA, UMTS, LTE, WiMax or Wi-Fi link.

The device 100 includes both volatile memory 214 and non-volatile (or non-transitory) memory 216. Both types of memory are accessed by the controller 200 via the system bus 202 and both types are connected directly to the system bus 202. The volatile memory 214 is RAM, DRAM or any other type of volatile memory. The volatile memory 214 is used by the controller 200 for the temporary storage of data, for instance when controlling the operation of another hardware or software component or moving data between components. The non-volatile memory 216 is ROM, flash memory, a hard disk or any other type of non-volatile memory. The non-volatile memory 216 stores computer readable instructions 218 as well as storing content and personal data (not shown). The controller 200 operates under the control of the computer-readable instructions 218 stored in the non-volatile memory 216, which include an operating system and additional software, middleware or firmware modules, and software applications.

The touch sensitive display 102 comprises a display part 220 and a tactile interface part 222. The controller 200 receives inputs from the tactile interface 222 and controls the display shown on the display part 220. The touch sensitive display 102 is connected to the system bus 202 by an interface 204b. The user input means 206 are connected to the system bus 202 via an interface 204c and include the physical keys 104a,104b and the microphone 108 as well as any other input means such as a QWERTY or numeric keypad or an accelerometer. The output means 208, which include the speaker 106 as well as other output means such as a light-emitting diode or a vibrating element, are connected to the system bus 202 via interface 204d.

The device 100 has a battery 224 which can provide the electrical power which is consumed by various parts of the device 100 during operation. In this example embodiment, the battery 224 is integrated in the device 100, in other words, the battery 224 is not intended to be removed or replaced by an end user and so is not easily removable. However, in some example embodiments, the battery 224 may be easily removable. More than one battery 224 may also be provided. The device 100 also has an electrical connector (not shown) for recharging the battery 224. In some example embodiments, electrical power may also be provided via the electrical connector or by another power source directly to the various parts of the device 100.

The device 100 also includes forced shutdown initiator apparatus 226 which, as will be explained in more detail below, initiates generation of a feedback signal in response to determining that an input has been selected throughout a first predetermined period of time and initiates a forced shutdown of the device 100 in response to determining that the input has been deselected within a second predetermined period of time after the initiating of the generation of the feedback signal. Accordingly, the apparatus 226 is operatively connected to the user input means 206, to the output means 208 and to a switching element 228.

The switching element 228 can be a relay such as a solid state relay or another type of switching element including one or more transistors. The switching element 228 controllably disconnects the battery 224 from various components of the device 100, thereby causing the device 100 to shut down. The components that are disconnected include the controller 200, the volatile memory 214, the transceiver 212 and the display 220. However, it will be appreciated that some parts of the device 100, for instance an internal clock (not shown), may still be provided with power, e.g., from an additional battery or capacitor (not shown). In example embodiments in which electrical power can also be provided directly via the electrical connector or from another power source, the switching element 228 or another switching element (not shown) may be configured so as to also enable this directly provided electrical power to be also controllably switched off.

In some example embodiments, the switching element 228 may be provided as part of a power management module that may be implemented as a power management integrated circuit or chip (not shown). Other functions of the power management module include providing a voltage to a processor core included in the controller 200 that is suited to a current activity of the core. For instance, when the device is in standby mode and the processor core is largely inactive, the power management module provides a relatively low voltage to the processor core. When the device is in active mode and the processor core is active, for instance when the device is playing back video content, the power management module provides a relatively high voltage to the processor core. The power management module in these example embodiments is configured to be responsive to a control signal requesting a forced shutdown to cease providing power to components including the controller 200, the volatile memory 214, the transceiver 212 and the display 220 but to remain providing power to an internal clock (not shown) and optionally one or more other components.

A forced shutdown involves shutting down the device 100, i.e. stopping the (main) power to the device 100, independently of the state of the device 100. Thus, a forced shutdown can be performed in all circumstances including when the device 100 is not responding because, for example, software 218 running on the device 100 has ‘crashed’ or ‘hung’. Initiation of a forced shutdown may also be independent of whether or not the device 100 is key-locked. By forcing shutdown of the device 100 and then powering on the device 100, a user can ‘reset’ the device 100 to try to recover from an unresponsive state. If the device 100 is operating normally, then a user can initiate a controlled shutdown, e.g. through a user interface provided through the touchscreen 102 and/or the physical keys 104a, 104b. A controlled shutdown involves, among other things, enabling the software 218 to finish storing any data before the power is switched off. During a forced shutdown, the software 218 simply stops running when the power is switched off and so, for example, any data which is in the process of being stored may be corrupted. However, in some example embodiments, a forced shutdown may involve some or all aspects of a controlled shutdown. For example, signals or messages may be provided to hardware or software 218 in the device 100 so that, if possible, certain pre-shutdown operations can be carried out before the power is switched off However, a forced shutdown always results in the device 100 being shutdown even if the device 100 is in a non-responsive state.

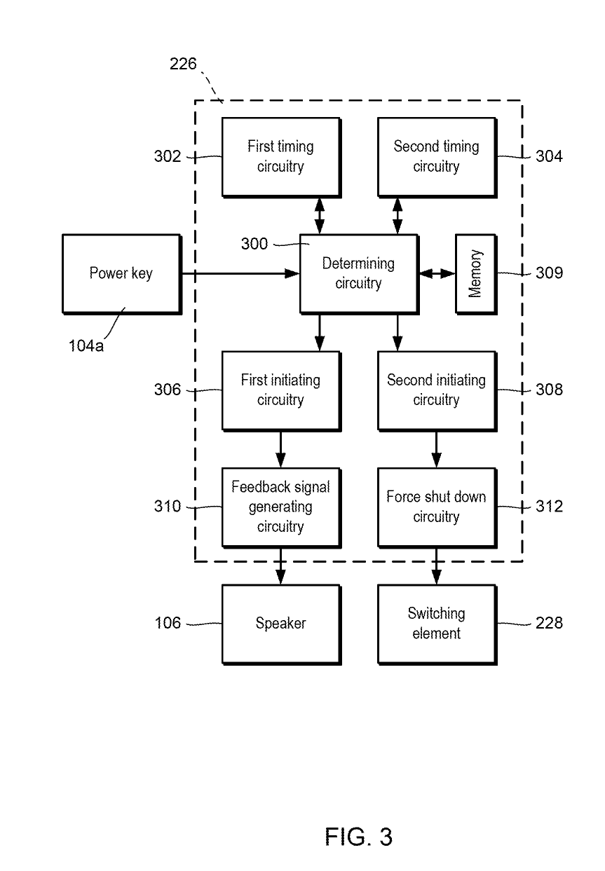

Referring mainly to FIG. 3, an example embodiment of the forced shutdown initiator apparatus 226 is shown in more detail. The apparatus 226 includes determining circuitry 300 operatively connected to each of first and second timers, specifically first and second timing circuitries 302, 304, first and second initiating circuitries 306, 308, and memory 309. The first and second initiating circuitries 306, 308 are operatively connected to a feedback signal generating circuitry 310 and forced shutdown circuitry 312 respectively. In this example embodiment, the feedback signal generating circuitry 310 and forced shutdown circuitry 312 are included in the apparatus 226. Alternatively, the feedback signal generating circuitry 310 and forced shutdown circuitry 312 may not be included in the apparatus 226 but may be partly or fully included in other parts of the device 100. However, as will be explained in more detail below, the circuitries 300, 302, 304, 306, 308, 309, 310, 312 are sufficiently independent of other hardware and software in the device 100 so that they are able to operate regardless of the state of the device 100. Indeed, any part of the apparatus 226 may be included in or shared with other parts of the device 100 provided that they can still operate sufficiently autonomously. Moreover, in some example embodiments, any two or more of the component parts of the apparatus 226 may be combined, in which case, operations said to be performed by the separate parts are performed by the combined parts. For example, the first and second initiating circuitries 306, 308 may be combined with the determining circuitry 300.

In this example embodiment, when the apparatus 226 is included in the device 100, the determining circuitry 300 is operatively connected to the power key 104a, the feedback signal generating circuitry 310 is operatively connected to the speaker 106, and the forced shutdown circuitry 312 is operatively connected to the switching element 228. Connections from the apparatus 226 to the other parts of the device 100 are made so as to enable the operations to be carried out regardless of the state of the device 100. Thus, direct electrical connections are used rather than, for example, attempting to communicate via the system bus 202.

In some example embodiments, the feedback signal generating circuitry 310 is connected to another speaker which may be an additional speaker integrated in the apparatus 226. Alternatively, the feedback signal generating circuitry 310 may be connected to another type of output means 208 such as a light emitting diode or a vibrating element. The feedback signal may also be generated by more than one output means 208, e.g., by the speaker 106 and a light emitting diode. In this case, the first initiating circuitry 306 may be connected to separate feedback signal generating circuitries for each of the outputs.

The determining circuitry 300 is operatively connected to the power key 104a so as to allow it to monitor the status of the key 104a, specifically whether or not the key 104a is pressed. The key 104a is a mechanical switch that is closed when pressed by a user and is biased to an open position otherwise, although the states could be reversed. Additional circuitry (not shown) may be provided so as to enable the key 104a to provide a suitable signal to the determining circuitry 300. In this example embodiment, the signal from the key 104a to the determining circuitry 300 is a voltage signal which is ‘low’ when the key 104a is not pressed and changes to ‘high’ when the key 104a is pressed. In other example embodiments, the determining circuitry 300 is operatively connected to the home key 104b or to any other physical key rather than to the power key 104a.

The first timing circuitry 302 starts, or re-starts, when provided with an input signal and provides an output signal indicating whether or not a first period of time has elapsed since being started or re-started. Similarly, the second timing circuitry 304 (re-)starts when provided with an input signal and provides an output signal indicating whether or not a second period of time has elapsed since being (re-)started. In each case, the input signal is a transition from a low to a high voltage, and the output signal is low voltage when the respective time period has not elapsed and changes to a high voltage when it has elapsed.

The predetermined time periods depend upon the characteristics of analogue elements of the circuitries 302, 304. Hence the time periods are set by the design of the device and are realized during manufacture.

In other example embodiments, data indicative of the first and second predetermined time periods may be stored in non-volatile memory (not shown) associated with the respective timing circuitries 302, 304. These data can be preset, for example during manufacture of the device 100 and can be set or changed subsequently, for example by the controller 200. In this case, the apparatus 226 is connected to the system bus 202 via an interface 204 so as to allow communications with the controller 200.

In some example embodiments, the first and second timing circuitries 302, 304 may be combined and have one or more or all of their parts in common.

The determining circuitry 300 is operatively connected to a memory element 309 so as to allow it to store data indicative of the apparatus 226 being in various states depending upon the history of key presses, as will be explained in more detail below. The memory element 309 may be a state machine, a collection of registers, or some other form.

The apparatus 226 has an initial, first, state, which it enters automatically whenever the device 100 is powered on.

When the key 104a is pressed, the apparatus 226 enters a second state. The second state is entered when the signal from the key 104a changes from ‘low’ to ‘high’, indicating that the key 104a has been pressed. This triggers starting of the first timing circuitry 302, i.e. in response to entering the second state, the determining circuitry 300 provides a signal to start the first timing circuitry 302. If the key 104a is released before the first predetermined time period has elapsed, as indicated by the signal from the first timing circuitry 302, the apparatus 226 re-enters the initial state. The first timing circuitry 302 may also be reset. Upon the key 104a again being pressed, the apparatus 226 again enters the second state, triggered by the signal from the key 104a changing from ‘low’ to ‘high’, and triggering starting of the first timing circuitry 302.

While in the second state, the apparatus 226 determines if the key 104a has been pressed for more than the first predetermined time period. This occurs by the determining circuitry 300 detecting that the first predetermined time period has elapsed, as indicated by the signal from the first timing circuitry changing from ‘low’ to ‘high’. On expiry of the first timer 302, the determining circuitry 300 checks whether the signal from the key 104a is ‘high’ indicating that the key 104a is (still) pressed and, if so, the apparatus 226 enters a third state. On entry into the third state, the apparatus 226 initiates generation of the feedback signal and starts the second timing circuitry 304.

In response to entering the third state, the determining circuitry 300 provides a signal to the first initiating circuitry 306 which then generates and provides a signal to the feedback signal generating circuitry 310. In this example embodiment, the signal to the first initiating circuitry 306 is a transition from a low to a high voltage and the signal to the feedback signal generating circuitry 310 is a pulse. When provided with this pulse, the feedback signal generating circuitry 310 generates and provides a suitable signal to the speaker 104 to cause the speaker 104 to produce an audible sound, such as one or more short ‘beeps’. The feedback signal generating circuitry 310 includes an oscillator (not shown) and an amplifier (not shown). In some example embodiments, parts of the feedback signal generating circuitry 310, e.g., the amplifier, are included in or shared with, other parts of the device 100. It will be appreciated that example embodiments in which feedback is provided via a different output means 208, such as a light emitting diode or a vibrating element, will include a different suitable feedback signal generating circuitry 310. A light emitting diode would be caused to produce one or more flashes, for example, or a vibrating element would be caused to produce one or more short vibration signals, for example.

Also in response to entering the third state, the determining circuitry 300 provides a signal to the second timing circuitry 304 to start the second timer 305. The apparatus 226 then remains in the third state either until the second timer expires or the key 104a is released, whichever is sooner.

While in the third state, the determining circuitry 300 monitors the signal from the key 104a to determine whether or not the key 104a is released. If the key 104a is released while the apparatus 226 in the third state, then forced shutdown is initiated. The determining circuitry 300 provides a signal to the second initiating circuitry 308 which, in turn, generates and provides a signal to the forced shutdown circuitry 312. Each of these signals are a transition from a low to a high voltage. When provided with the signal from the second initiating circuitry 308, the forced shutdown circuitry 312 provides a suitable signal to the switching element 228 to cause the switching element 228 to switch off the (main) electrical power to and hence shut down the device 100. In this example embodiment, the switching element 228 makes a connection completing the electrical power circuit when it is provided with a ‘high’ voltage signal and breaks the connection and hence the circuit when it is provided with a ‘low’ voltage signal. In some example embodiments, prior to providing the signal to the switching element 228, the forced shutdown circuitry 312 may carry out other operations, including, for example, providing a message or signal to the controller 200 via a connection (not shown) to the system bus 202 or other suitable means.

Expiry of the second timer is detected by the determining circuitry 300 being provided with a signal from the second timing circuitry 304 indicating that the second predetermined time period has elapsed, whereupon the apparatus 226 enters a fourth state. The apparatus 226 remains in the fourth state until the key 104a is released. When the key 104a is released, the apparatus 226 re-enters the initial, first state. While in the fourth state, the apparatus 226 does not initiate generation of the feedback signal or the forced shutdown, i.e., these functions are disabled. However, while in the initial, first state, these functions are enabled, as described above.

It will also be appreciated that other parts of the device 100 may carry out other operations in response to the key 104a being pressed and/or released. For example, the touchscreen 102 may be switched off. However, operations carried out by the apparatus 226 are independent of any such other operations.

In these example embodiments, the first predetermined time period is 10 seconds and the second predetermined time period is 1 second. Alternatively, the first and second predetermined time periods may each have different lengths to these. Generally though, the first predetermined time period is relatively long and the second predetermined time period is relatively short. For example, the first predetermined time period may be between 5 seconds and 30 seconds in length and the second predetermined time period may be between 0.5 seconds and 3 seconds in length. In some example embodiments, the first predetermined time period is at least ten times as long as the second predetermined time period. In some example embodiments, the first predetermined time period is at least four times as long as the second predetermined time period.

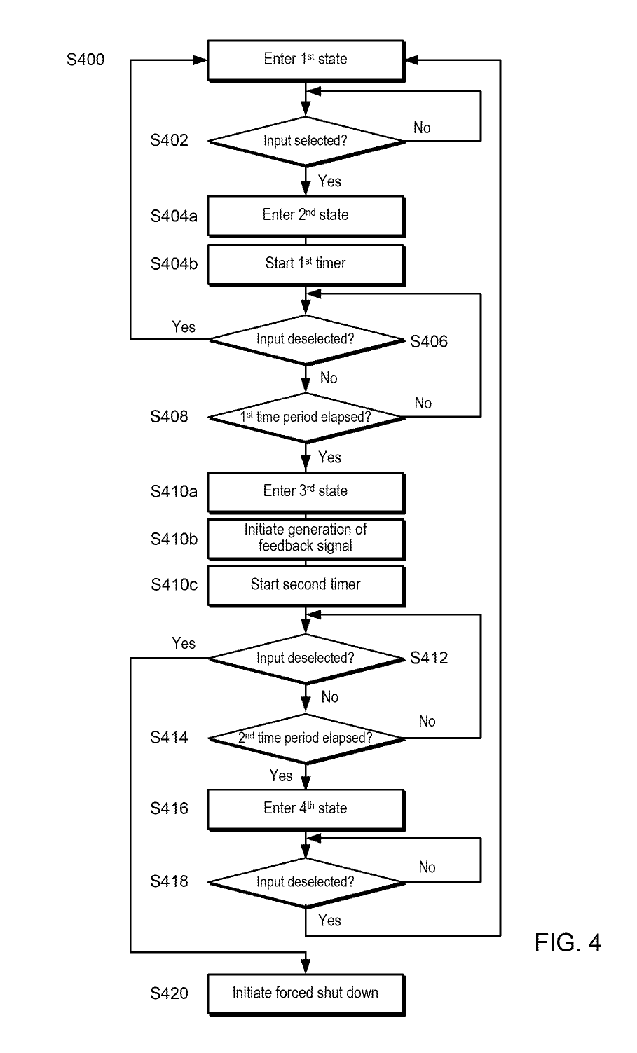

Referring to FIG. 4, a method of operation of the apparatus 226 of FIG. 3 is shown. This supplements the operation described above with reference to FIG. 3.

At step S400, an initial, first state is entered, e.g., after switching on of the device 100. At step S402, it is determined whether or not an input is selected and this step S402 is repeated, i.e., the status of the input is monitored, until the input is selected. If the input is selected, then a second state is entered (see step S404a) and, at substantially the same time, a first timer is started (see step S404b). Then, it is determined, at step S406, if the input has been deselected and, if not, at step S406, if the first predetermined time period has elapsed after the selecting of the input. These steps S406, S408 are repeated, i.e., the statuses of the input and of the first timer are monitored until either the input is deselected or the first predetermined time period has elapsed. If the input is deselected before the first predetermined time period has elapsed, then the process returns to step S400, i.e. the initial, first state is re-entered. If the first predetermined time period has elapsed before the input is deselected, then a third state is entered (see step S410a) and, at substantially the same time, generation of a feedback signal is initiated (see step S410b) and a second timer is started (see step S410c). Then, it is determined, at step S412, if the input has been deselected and, if not, at step S414, if the second predetermined time period has elapsed after the initiating of the generation of the feedback signal. These steps S412 and S414 are repeated, i.e., the statuses of the input and of the second timer are monitored until either the input is deselected or the second predetermined time period has elapsed. If the input is deselected before the second predetermined time period has elapsed, then, the process goes to step S420 and forced shutdown is initiated. If the second time period has elapsed before the input is deselected, then a fourth state is entered (see step S416). Then, at step S418, it is determined if the input has been deselected and this step S418 is repeated, i.e., the status of the input is monitored, until the input is deselected. Thus, the initiation of the generation of the feedback signal and of the forced shutdown is disabled until the input is deselected. If the input is deselected, then the process returns to step S400, i.e., the initial, first state is re-entered, i.e. the initiation of the generation of the feedback signal and of the forced shutdown is enabled once more.

Thus, the herein disclosed example embodiments provide a way of enabling a forced shutdown of the device 100 to be initiated by a user in a relatively straightforward manner. The timed procedure means that forced shutdown can be initiated using fewer and/or more readily accessible inputs and, in some of the disclosed example embodiments, even using just one physical key such as a power key. Thus, the difficulties for a user associated with, for example, pressing a number of different keys in combination or obtaining and using a suitable tool to access a recessed input are reduced. Moreover, the feedback signal provides an intuitive prompt to release the input. Overall, the procedure is more straightforward for the user and, for example, it is even possible for a user to discover the procedure for himself or herself when the device 100 is not responding. At the same time, the herein disclosed example embodiments provide a way of reducing the likelihood of an unintended forced shutdown. This is due to the requirements of a relatively long selection of the input followed by a critically timed release of the input. An input, particularly an input such as a power key, could be accidentally selected by a user or by an object, for example when the device 100 is being carried in a bag or in a pocket. However, if the input is released after a short period of time, then forced shutdown will not be initiated. Moreover, even if the input is accidentally selected for a longer period of time, for example because an object is pressing against it, it is unlikely that the input would be released during the relatively short time period which would cause the forced shutdown to be initiated.

It should be realized that the foregoing example embodiments should not be construed as limiting. Other variations and modifications will be apparent to persons skilled in the art upon reading the present application.

For instance, additional feedback signals may be provided to the user while the input is selected or after the input has been released. For example, additional feedback signals, such as repeated signals, may be provided while the input is selected before the generation of the feedback signal and/or before and/or after the second predetermined time periods has elapsed.

In some example embodiments, the determining circuitry 300 may be operatively connected to more than one physical key, such as the keys 104a and 104b. In this case, operation is similar to that described above except that the keys 104a, 104b are both pressed and then both released in order to initiate forced shutdown. In some example embodiments, the determining circuitry 300 may even be operatively connected to another type of user input means, e.g., to the tactile interface part 212 of the touchscreen 102 or to an accelerometer. However, since the apparatus 226 cannot generally rely on the controller 200 to process signals from the user input means 206 (or indeed for performing any other actions), additional circuitry may carry out such processing and providing a suitable signal to the determining circuitry 300.

Moreover, the disclosure of the present application should be understood to include any novel features or any novel combination of features either explicitly or implicitly disclosed herein or any generalization thereof and during the prosecution of the present application or of any application derived therefrom, new claims may be formulated to cover any such features and/or combination of such features.

Also, although the apparatus 226 has been described as being implemented purely in hardware, without any software element, is may instead incorporate a microcontroller or other such hardware that performs some or all of the stated functions under control of software. In this case, the microcontroller or other hardware may not be shared with other components of the device 100 so that proper operation of the apparatus 226 may be more easily assured.

As used in this application, the term ‘circuitry’ refers to all of the following:

(a) hardware-only circuit implementations (such as implementations in only analog and/or digital circuitry) and
(b) to combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and
(c) to circuits, such as a microprocessor(s) or a portion of a microprocessor(s), that require software or firmware for operation, even if the software or firmware is not physically present.

What is claimed is:

1. A method comprising:
initiating generation of a feedback signal in response to determining that an input has been selected throughout a first predetermined period of time; and
initiating a forced shutdown of a device in response to determining that the input has been deselected within a second predetermined period of time after the initiating of the generation of the feedback signal.

2. The method of claim 1, further comprising:
disabling the initiation of the forced shutdown of the device in response to determining that the input has remained selected throughout the second predetermined period of time after the initiating of the generation of the feedback signal.

3. The method of claim 1, comprising:
entering a second state from an initial, first state in response to determining that the input has been selected;
causing a first timer to start in response to entering the second state, the first timer defining the first predetermined period of time;
entering a third state from the second state in response to determining that the input has not been deselected prior to expiry of the first timer;
causing a second timer to start in response to entering the third state, the second timer defining the second predetermined time period; and
initiating the forced shutdown in response to determining that the input has been deselected prior to expiry of the second timer.

4. The method of claim 3, comprising:
entering the first, initial state from the second state in response to determining that the input has been deselected prior to expiry of the first timer.

5. The method of claim further comprising:
refraining from initiating forced shutdown in response to determining when in the third state that the input has not been deselected prior to expiry of the second timer.

6. The method of claim 5, further comprising:
entering the first, initial state from the fourth state in response to determining that the input has been deselected.

7. The method of claim 1, wherein the input is an input to a single physical key.

8. The method of claim 1, wherein initiating forced shutdown comprises causing removal of the supply of electrical power from an integrated battery.

9. The method of claim 1, wherein the first predetermined period is at least four times as long as the second predetermined period.

10. Apparatus comprising:
a determining device; and
first and second initiating devices;
wherein:
the determining device is configured to determine that an input has been selected throughout a first predetermined period of time;
the first initiating device is configured to initiate generation of a feedback signal in response to the determining that the input has been selected throughout the first predetermined period of time;
the determining device is further configured to determining that the input has been deselected within a second predetermined period of time after the initiating of the generation of the feedback signal; and
the second initiating device is configured to initiate a forced shutdown of a device in response to the determining that the input has been deselected within the second predetermined period of time after the initiating of the generation of the feedback signal.

11. The apparatus of claim 10, wherein the determining device is further configured to disable the initiation of the forced shutdown of the device in response to determining that the input has remained selected throughout the second predetermined period of time after the initiating of the generation of the feedback signal.

12. The apparatus of claim 10, wherein the determining device is configured to:
cause the apparatus to enter a second state from an initial, first state in response to determining that the input has been selected;
cause a first timer to start in response to entering the second state, the first timer defining the first predetermined period of time;
cause the apparatus to enter a third state from the second state in response to determining that the input has not been deselected prior to expiry of the first timer;
cause a second timer to start in response to entering the third state, the second timer defining the second predetermined time period; and
determine that the input has been deselected prior to expiry of the second timer;
and the second initiating devices is configured to:
initiate the forced shutdown in response to the determining that the input has been deselected prior to expiry of the second timer.

13. The apparatus of claim 12, wherein the determining device is configured to cause the apparatus to enter the first, initial state from the second state in response to determining that the input has been deselected prior to expiry of the first timer.

14. The apparatus of claim wherein the determining device is further configured to cause the apparatus to refrain from initiating forced shutdown in response to determining when in the third state that the input has not been deselected prior to expiry of the second timer.

15. The apparatus of claim 14, wherein the determining device is further configured to cause the apparatus to enter the first, initial state from the fourth state in response to determining that the input has been deselected.

16. The apparatus of claim 10, wherein the input is an input to a single physical key.

17. The apparatus of claim 10, wherein the second initiating device is configured to initiate forced shutdown comprising causing removal of the supply of electrical power from an integrated battery.

18. The apparatus of claim 10, wherein the first and second initiating devices constitute a single initiating device.

19. The apparatus of claim 10, wherein determining circuitry constitutes the determining device, first initiating circuitry constitutes the first initiating device, and second initiating circuitry constitutes the second initiating device.

20. The apparatus of claim 10, wherein the apparatus is the device and further comprises:
user interface circuitry and user interface software configured to facilitate user control of at least some functions of the device though use of a display and configured to respond to user inputs; and
a display and display circuitry configured to display at least a portion of a user interface of the device, the display and display circuitry configured to facilitate user control of at least some functions of the device.

21. (canceled)

22. (canceled)
